(19) United States
(12) Patent Application Publication
(10) Pub. No.: US 2022/0187885 A1
(43) Pub. Date: Jun. 16, 2022

(54) CONTROLLING SPEED OF COOLING ELEMENTS

(71) Applicant: Hewlett-Packard Development Company, L.P., Spring, TX (US)

(72) Inventors: Hung-Wen Chang, Taipei City (TW); Chien-Tu Cheng, Taipei City (TW); Hao-Wu Yang, Taipei City (TW)

(73) Assignee: Hewlett-Packard Development Company, L.P., Spring, TX (US)

(21) Appl. No.: 17/419,744

(22) PCT Filed: Sep. 6, 2019
(86) PCT No.: PCT/US2019/049906

§ 371 Date: Jun. 30, 2021

(51) Int. Cl. G06F 1/20; H05K 7/20

(52) U.S. Cl. CPC G06F 1/206; H05K 7/20209; G06F 1/203

(57) ABSTRACT

Examples of devices and methods for controlling speed of cooling elements are discussed. The device comprises a first temperature reader to measure an ambient temperature in the vicinity of the device. The device further comprises a processor to control a speed of a cooling element of the device based on a comparison of the ambient temperature with a first threshold temperature.

### BACKGROUND

Computing devices include heat-generating components, such as a central processing unit (CPU) or a graphics processing unit (GPU), which can result in an increase in temperature of the component and of a chassis of the device. The devices also include cooling elements, such as fans to cool down the heat-generating components and the device chassis. The amount of heat generated by the various components varies based on the usage of the device and operation of the cooling elements may be varied accordingly. Far example, if the CPU becomes hot, the fan may be turned on or, if the fan is already on, the fan speed may be increased.

### BRIEF DESCRIPTION OF DRAWINGS

The following detailed description references the figures, wherein:

FIG. 1 illustrates a schematic of an example device, according to an example implementation of the present subject matter;

FIG. 2 illustrates a schematic of an example device, according to another example implementation of the present subject matter;

FIG. 3(a) illustrates a schematic of a temperature reader, according to an example implementation of the present subject matter;

FIG. 3(b) illustrates placement of different temperature readers on a device, according to an example implementation of the present subject matter;

FIG. 4 illustrates a method for controlling speed of cooling element, according to an example implementation of the present subject matter:

FIG. 5 illustrates a method for controlling speed of cooling element, according to another example implementation of the present subject matter; and

FIG. 6 illustrates a computing environment implementing a computer readable medium for controlling speed of cooling element, according to an example implementation of the present subject matter.

### DETAILED DESCRIPTION

Computing devices, such as laptop computers, tablets, and desktop computers, may include components that generate heat. For example, a CPU of the device may generate more heat with an increase in the processing load of the device. As the processing load decreases, the amount of heat generated may also reduce. The heat generated may lead to an increase in temperature at certain localized portions within the device, referred to as hotspots. Operation of the processing component at increased temperatures may reduce the efficiency of the computing device. In addition, the outer surfaces or chassis of the device may also heat up and the device may become so hot that it affects the user experience.

To reduce the temperature, cooling elements, such as a fan, are provided within the device to cool down the heat-generating components and the device. For example, the fan may be turned on if the hotspot temperature or a component temperature increases. If there is a further increase in the temperature, the speed of the fan may be increased.

The temperature of the device components may be determined using temperature sensors. These temperature sensors may be placed on device components, such as on the CPU, GPU, or on the motherboard to which the device components are connected. In some cases, because of an increase in computational load that leads to an increase in temperature at a hotspot, the fan speed may increase. The increased fan speed may result in noisy operation and negative user experience, whereas the device may not be so hot that it affects the user experience.

For example, if the fan speed is changed based on readings obtained from temperature sensors provided on the processing units, such as CPU or GPU, it may lead to increased fan speeds for small temperature variations. In case of a sudden increase in the temperature at these units for short time periods because of an increase in the computing processes, the fan speed may increase. However, a temperature of an external surface of the device in contact with a user may not be very hot.

In other examples, the fan speed may be controlled based on on-board temperature sensors placed on the motherboard of the device. The temperature at the motherboard may increase because of the connected components, leading to a sudden increase in fan speed. As the motherboard cools down slower than the components, the fan speed is reduced slower than the decrease in processing activity. Thus, while the on-board temperature sensors may indicate that the motherboard components are hot, the temperature of an external surface of the device in contact with a user may not be very hot.

This may lead to poor user experience because the noise of the fan may be present even when the user feels that the device chassis temperature is tolerable. In addition, this may lead to poor energy usage and reduced efficiency of the device because of the high speed of operation of the fan.

Aspects of the present subject matter relate to controlling a speed of cooling elements in devices where a processor controls the speed based on temperatures determined by temperature readers placed at various locations in the device. In an example, the temperature readers may determine a hotspot or component temperature and an ambient temperature in the vicinity of the device. In another example, the temperature readers may determine a contact temperature and an ambient temperature. The device may be a desktop computing device, a laptop, a tablet, and the like.

In one example, the device comprises a first temperature reader to measure an ambient temperature, a second temperature reader to measure a component temperature of a component of the device, a cooling element, and a processor to control a speed of the cooling element. The processor controls the speed of the cooling element based on a comparison of the ambient temperature with a first threshold temperature and based on one of: the component temperature and a difference between the ambient temperature and the component temperature.

In various examples of the present subject matter, the device may comprise a third temperature reader to measure a contact temperature. The contact temperature is a temperature of an area of the device that is to come in contact with a user. The speed of the cooling element may also be controlled based on a comparison between the contact temperature and a second threshold temperature.

Thus, the present subject matter provides for better user experience by changing the fan speed based on the user's environment, such as ambient temperature and the contact temperature, along with the hotspot temperature. For example, although the CPU or GPU temperature may increase, the fan speed may not be increased if the contact temperature is tolerable or if the ambient temperature is low and the cooling may be expected to be efficient at low fan speeds. In another example, if the ambient temperature is high, the fan speed may not be increased where the CPU or GPU temperature is not substantially higher than the ambient temperature, as the CPU or GPU temperature may not be expected to reduce to temperatures lower than the ambient temperature even at high fan speeds. This provides a better user experience by controlling the fan speed and thereby the amount of noise generated by the fan. In addition, this helps to reduce power consumed by the cooling element and improve efficiency of the cooling element and the device.

The following description refers to the accompanying drawings. Wherever possible, the same reference numbers are used in the drawings and the following description to refer to the same or similar parts. While several examples are described in the description, modifications, adaptations, and other implementations are possible. Accordingly, the following detailed description does not limit the disclosed examples. Instead, the proper scope of the disclosed examples may be defined by the appended claims.

Example implementations of the present subject matter are described with regard to personal computers (PCs) and laptop computers. Although not described, it will be understood that the implementations of the present subject matter can be used with other types of devices as well, such as tablets, smart devices, and the like.

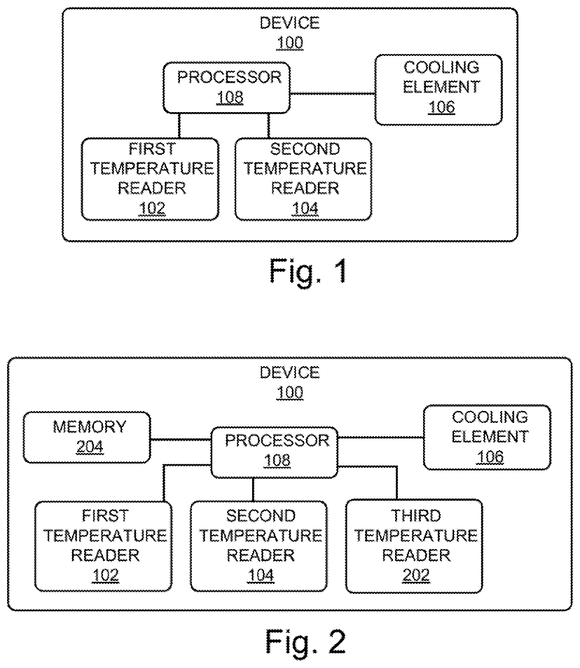

FIG. 1 illustrates a schematic of a device 100, according to an example implementation of the present subject matter. In example implementations, the device 100 may be desktop, a laptop, a server, and the like. The device 100 comprises a first temperature reader 102, a second temperature reader 104, a cooling element 106, and a processor 108. In various examples, the temperature readers 102 and 104 may be implemented as thermocouples, thermistors, resistance temperature detectors, and the like.

In operation, the first temperature reader 102 measures an ambient temperature in the vicinity of the device 100. The first temperature reader may be disposed on a portion of the device 100 that is away from heat-generating components. In one example, where the device 100 is a laptop, the first temperature reader 102 may be placed on a portion of the device chassis behind a screen of a laptop.

The second temperature reader 104 measures a component temperature of a component of the device 100. The second temperature reader 104 may be disposed at a location that is in proximity to a component that is a heat-generating component of the device 100. In an example, the second temperature reader 104 may be placed on a CPU or a CPU of the device 100. In another example, the second temperature reader 104 may be placed on a motherboard of the device 100, in the vicinity of the heat-generating component. In other examples, the second temperature reader 104 may measure hotspot temperatures at other hotspot locations in the device 100.

The device 100 further comprises a cooling element 106. In some examples, the cooling element 106 may be a fan. The speed of the cooling element may correspond to noise generated by the cooling element. For example, the noise generated by the fan may increase with an increase in speed of the fan. The cooling element 106 may be disposed suitably in the device 100 to cool the heat-generating components, hotspot locations, and the device 100. While the description is provided with reference to a fan as a cooling element, the teachings of the present subject matter can be applied to other cooling elements, such as pumps in liquid-cooled devices, for less noisy and more efficient operation.

The processor 108 may be coupled to the temperature readers 102 and 104 and the cooling element 106 to control the speed of the cooling element 106. In an example, the processor 108 may generate control instructions for controlling the speed of the cooling element 106. The processor 108 may be implemented as a dedicated processor, a shared processor, or a plurality of individual processors, some of which may be shared. The processor 108 compares the ambient temperature measured by the first temperature reader 102 to a first threshold temperature. In various examples, the value of the first threshold temperature may be preset and stored in the device 100. In other examples, the value of the first threshold temperature may be determined based on device configuration, device specification, and the like. For example, the first threshold temperature may be determined as a temperature that is less than a temperature limit of an external surface of the device chassis, as per the device specification, by a certain amount, such as 15° C. Hence, if the temperature limit is 40° C., the first threshold temperature may be 25° C.

In one example, the processor 108 controls the speed of the cooling element 106 based on a comparison of the ambient temperature with the first threshold temperature and based on one of: the component temperature and the difference between the ambient temperature and the component temperature.

According to an example implementation of the present subject matter, when the ambient temperature is less than the first threshold temperature, the speed of the cooling element is controlled based on the component temperature to keep the temperature of the component below the design specification. As the ambient temperature is low, the component and device chassis may be cooled sufficiently fast by ambient air so that it does not affect the operations or user experience. Further, as the chassis heats up slower than the component, even if the component temperature reaches close to the design specification, the chassis temperature may remain below the design specification, thus allowing for efficient use of the cooling element 106.

For example, consider the case where the ambient temperature is less than 2.5° C. and the device specification is 40° C. In this example, when the component temperature is within a first temperature range, such as between 30° C. and 35° C., the speed of the cooling element is changed to a first speed, corresponding to a low noise, such as 28 dBA. When the component temperature is higher and within a second temperature range, for example, between 35° C. and 37° C., the speed of the cooling element is changed to a second speed for a higher cooling rate, but corresponding to a higher noise, such as 32 dBA. In case the component temperature is within a third temperature range close to the device specification, for example, between 37° C. and 40° C., the speed of the cooling element is changed to a third speed for an even higher cooling rate, but corresponding to an even higher noise, such as 35 dBA. Thus, the speed of the fan and corresponding noise generated by the fan is controlled based on the component temperature allowing for a better user experience and improved efficiency.

In another example, when the ambient temperature is greater than the first threshold temperature, the device 100 may not cool down fast without increasing the speed of the cooling element 106. However, a higher speed may not help in increasing a cooling rate if the difference between the ambient and component temperatures is low, as the temperature of the component may not be cooled to a temperature less than the ambient temperature. In this case, the speed of the cooling element 106 may be controlled based on a temperature difference between the component temperature and the ambient temperature so that the cooling element 106 may be used to efficiently supplement the cooling provided due to the temperature difference.

Hence, for example, when the difference between the component temperature and the ambient temperature is in a fourth temperature range, such as less than 7° C., the speed of the cooling element 106 is changed to the first speed, generating a noise, such as 28 dBA. When the difference between the component temperature and the ambient temperature is within a fifth temperature range, such as between 7° C. and 12° C., the speed of the cooling element is changed to the second speed, generating a noise, such as 32 dBA. When the difference between the component temperature and the ambient temperature is within a sixth temperature range, such as between 12° C. and 15° C., the speed of the cooling element is changed to the third speed, generating a noise, such as 35 dBA. Thus, the speed of the fan and corresponding noise generated by the fan is controlled based on the difference between the ambient and component temperature, allowing for a better user experience and improved efficiency.

In various example implementations, the temperature ranges and speed setting to be used for controlling the speed of the cooling element 106 may be stored in a memory. In some examples, a temperature of a portion of the device 100 that is to come in contact with the user may be used additionally for controlling the speed of the cooling element 106 as further described below.

FIG. 2 illustrates a schematic of an example device 100, according to another example implementation of the present subject matter. The device 100 may further comprise a third temperature reader 202 to measure a contact temperature. The contact temperature is a temperature of an area of the device that is to come in contact with a user. For example, the contact temperature may be the temperature of a palm rest area of a laptop, a trackpad area of a laptop, an area where the device 100 is held when carrying it, or the like. The third temperature reader 202, like the temperature readers 102 and 104, may be implemented as a thermocouple, a thermistor, a resistance temperature detector, and the like. The third temperature reader 202 may be disposed on an inside portion of the device chassis, the corresponding external portion of which comes in contact with the user. In various examples, the third temperature reader 202 may be disposed on a portion of the device chassis corresponding to the palm rest area in a laptop, a back portion of a laptop that is used for carrying the laptop, and the like.

In some examples, the speed of the cooling element 106 is additionally controlled based on a comparison between the contact temperature and a second threshold temperature. For example, when the contact temperature is more than the second threshold temperature, the speed of the cooling element 106 may be increased to a speed greater than a current speed, though as per the ambient and component temperatures the current speed may also provide efficient cooling. On the other hand, when the contact temperature is less than the second threshold, the speed of the cooling element 106 may be controlled based on the ambient and component temperatures as discussed above with reference to FIG. 1.

In some examples, the second threshold temperature may be determined based on a temperature that is comfortable for a user when the user comes in contact with the device, for example, 35° C. In another example, the second threshold temperature may be a temperature that a user can safely tolerate and that does not cause a burn or injury to the user. The value of the second threshold temperature may be preset and stored in the device 100.

In one example, the device 100 further comprises a memory 204. The memory 204 may be communicatively coupled to the processor 108. Among other capabilities, the processor 108 may fetch and execute computer-readable instructions stored in the memory 204. The memory 204 may include any non-transitory computer readable medium including, for example, volatile memory such as RAM, or non-volatile memory such as EPROM, flash memory, and the like.

In some examples, the memory 204 stores a look-up table that maps the different speeds of the cooling element 106 to different temperature ranges. As discussed, the speed of the cooling element 106, for example, a fan, corresponds to a certain amount of noise generated by the fan. The look-up table may comprise the speeds, the corresponding noise generated, or a combination thereof. The different temperature ranges may be temperature ranges of the component temperature and the temperature ranges of a difference between the ambient temperature and the component temperature for controlling the speed of the cooling element 106. In some examples, the memory 204 may also store values of the first threshold temperature and the second threshold temperature.

In various implementations as discussed herein, the processor 108 controls the speed of the cooling element 106 based on the ambient temperature, the component temperature, and the contact temperature received from the temperature readers; and the threshold temperatures and mapping between the temperature ranges and speeds as stored in the look-up table. In some examples, the temperature readers used for determining the ambient temperature, the component temperature, and the contact temperature may be slim temperature readers that may be easily placed at different locations in the device 100 and may be connected to the processor 108.

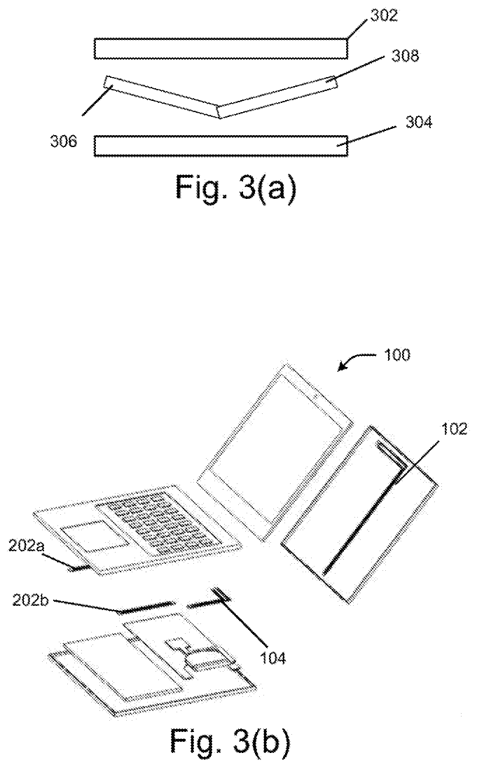

FIG. 3(a) illustrates a schematic of a temperature reader, according to an example implementation of the present subject matter. The first, second, and third temperature readers 102, 104, and 202, respectively, may be thermocouples disposed between a first thermally conductive substrate 302 and a second thermally conductive substrate 304. In some examples, the thermocouple may be thin films of two different metals 306 and 308 joined together on one end. For example, the metals 306 and 308 may be selected from copper, aluminum, platinum, and the like. Further, the thermally conductive substrates 302 and 304 may be thermally conductive plastics, metal films, and the like. In some examples, the temperature readers are thin and flexible. The flexibility and thinness of the temperature readers 102, 104, and 202, allows them to be placed anywhere within the device 100 so that they do not occupy too much space and allows for easy routing of wires for connection to the processor 108.

FIG. 3(b) illustrates placement of different temperature readers on a device, according to an example implementation of the present subject matter. In an example, the device 100 is a laptop computer. The first temperature reader 102 may be placed on a device chassis behind the screen of the laptop to measure the ambient temperature. The second temperature reader 104 may be placed near the CPU of the laptop. The third temperature reader 202a may be placed on a portion of the device chassis near the palm rest area of the laptop. Mother third temperature reader 202b may be placed on a portion of the device chassis behind the motherboard, which may come in contact with a user when carrying the laptop.

Although the device 100 has been described using the first, second, and third temperature readers 102, 104, and 202, any number of temperature readers may be used to determine the ambient, component, and contact temperatures. For example, a plurality of first temperature readers may be located at different portions of the device 100. In another example, a plurality of second temperature readers may be located in proximity to different heat generating components or hotspot locations of the device 100.

Furthermore, the device 100 may include a plurality of cooling elements 106 and the speed of each cooling element 106 may be individually controlled by the processor 108 using the teachings of the present subject matter.

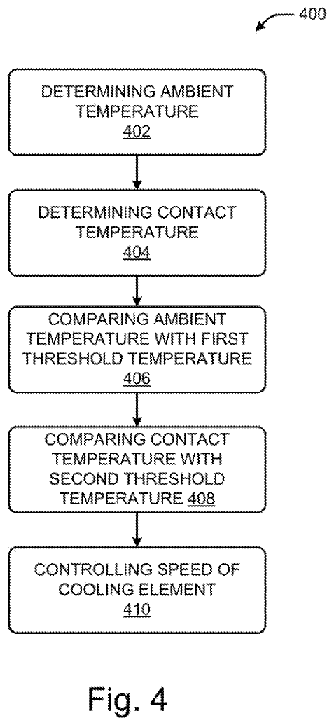

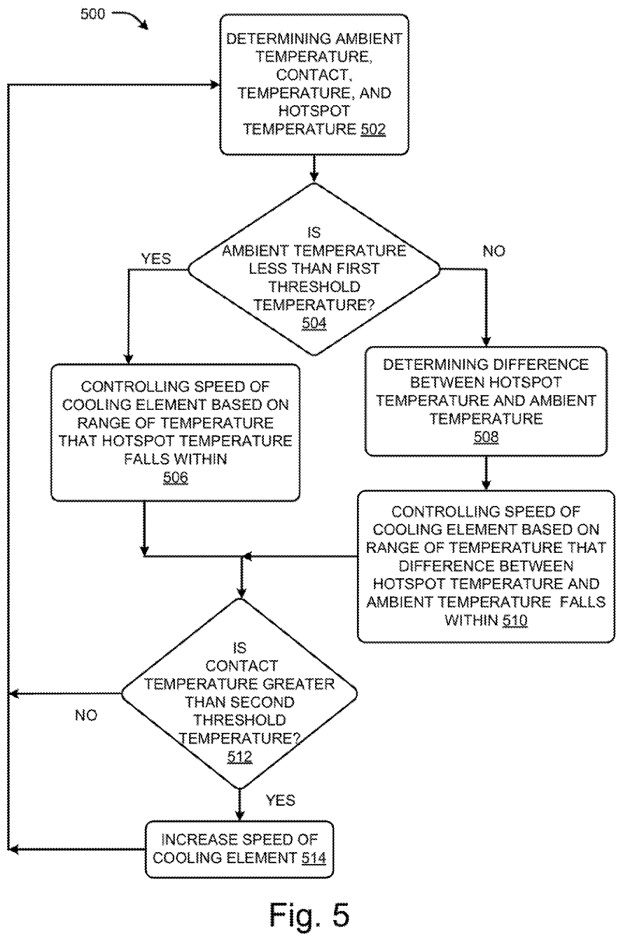

FIGS. 4 and 5 illustrate example methods 400 and 500 for controlling speed of a cooling element of a device, according to example implementations of the present subject matter. The order in which the methods 400 and 500 are described is not intended to be construed as a limitation, and some of the described method blocks can be combined in a different order to implement the methods or alternative methods. Furthermore, the methods 400 and 500 may be implemented in any suitable hardware, computer readable instructions, or combination thereof. The steps of the methods 400 and 500 may be performed by either a system under the instruction of machine-executable instructions stored on a non-transitory computer readable medium or by dedicated hardware circuits, microcontrollers, or logic circuits. Herein, some examples are also intended to cover non-transitory computer readable medium, for example, digital data storage media, which are computer readable and encode computer-executable instructions, where said instructions perform some or all of the steps of the methods 400 and 500. While the methods 400 and 500 may be implemented in any device, the following description is provided in the context of device 100 as described earlier with reference to FIGS. 1-3 for ease of discussion.

Referring to FIG. 4, in one example, at block 402, the ambient temperature is determined, in an example, a processor, such as the processor 108, determines the ambient temperature from a first temperature sensor of the device 100. The first temperature sensor may correspond to the first temperature reader 102.

At block 404, the contact temperature is determined. For example, the processor 108 determines the contact temperature from a second temperature sensor of the device 100. The second temperature sensor may correspond to the third temperature reader 202. As explained before, the contact temperature is a temperature of an area of the device that is to come in contact with a user.

At block 406, the ambient temperature is compared to the first threshold temperature and at block 408 the contact temperature is compared to the second threshold temperature. For example, the processor 108 of the device 100 may fetch the first and second temperature thresholds from the memory 204 for comparison with the ambient and contact temperatures.

At block 410, the speed of the cooling element is controlled based on the comparisons. For example, if the ambient temperature is less than the first threshold temperature, the processor 108 may control the speed of the cooling element 106 based on the component temperature. On the other hand, if the ambient temperature is greater than the first threshold temperature, the processor 108 may control the speed of the cooling element 106 based on a difference between the ambient and the component temperatures. Further, if the contact temperature is greater than the second threshold temperature, the processor 108 may increase the speed of the cooling element 106.

Referring to FIG. 5, at block 502, an ambient temperature, a contact temperature, and a hotspot temperature are determined for a device. For example, the processor 108 may determine the ambient temperature, the contact temperature, and the hotspot temperature from a first temperature sensor, a second temperature sensor, and a third temperature sensor, respectively. The first temperature sensor may be, for example, the first temperature reader 102 that measures the ambient temperature in the vicinity of the device 100. The second temperature sensor, may be for example, the third temperature reader 202 that measures the temperature of an area that is likely to come in contact with a user as the contact temperature. The third temperature sensor, may be, for example, the second temperature reader 104, that measures the hotspot temperature. In various examples, the hotspot temperature may be a temperature in the vicinity of a heat-generating component of the device 100, such as a CPU, GPU, and the like.

At block 504, it is determined if the ambient temperature is less than the first threshold temperature.

If the ambient temperature is less than the first threshold temperature, at block 506, the speed of the cooling element 106 is controlled based on a range of temperatures that the hotspot temperature falls within to maintain the hotspot temperature below a device specification. In an example, a device specification may have a temperature limit of an external surface of the device chassis as 40T. When the hotspot temperature is within a first temperature range, for example, between 30° C. and 35° C., the speed of the cooling element is changed to a first speed, corresponding to a noise level, such as 28 dBA. When the hotspot temperature is within a second temperature range, for example, between 35° C. and 37° C., the speed of the cooling element is changed to a second speed for higher cooling, but corresponding to a higher noise level, such as 32 dBA. When the hotspot temperature is within a third temperature range, for example, between 37° C. and 40° C., the speed of the cooling element is changed to a third speed for even higher cooling, but corresponding to an even higher noise level, such as 35 dBA. In one example, in case the hotspot temperature increases to more than the design specification limit of 40° C., the speed of the fan may be increased to a maximum speed.

Further, from block 504, if the ambient temperature is greater than the first threshold temperature, the method 500 proceeds to block 508 where a difference between the hotspot temperature and the ambient temperature is determined.

Next, at block 510, the speed of the cooling element is controlled based on a range of temperature that a difference between the hotspot temperature and the ambient temperature falls within. In one example, when the difference between the hotspot temperature and the ambient temperature is in a fourth temperature range, such as, less than 7° C., the speed of the cooling element is changed to the first speed. When the difference between the hotspot temperature and the ambient temperature is within a fifth temperature range, such as, between 7° C. and 12° C., the speed of the cooling element is changed to the second speed. When the difference between the hotspot temperature and the ambient temperature is within a sixth temperature range, such as, between 12° C. and 15° C., the speed of the cooling element is changed to the third speed.

From blocks 506 and 510, the method 500 proceeds to block 512 where the contact temperature is compared to the second threshold temperature, and at block 514, the speed of the cooling element 106 is controlled based on the comparison. In an example, if the contact temperature is greater than the second threshold temperature, the speed of the cooling element 106 is increased to a speed higher than a current speed and the method 500 may then restart from block 502. If the contact temperature is not greater than the second threshold temperature the method 500 proceeds to block 502 to determine the ambient temperature, contact temperature, and the hotspot temperature.

In various examples, as the speed of the cooling element 106 is controlled based on different temperature measurements as described herein, the noise generated by the cooling element 106, which corresponds to speed of the cooling element 106, is better controlled, providing for a better user experience and more efficient utilization of the device 100.

In some examples, the speed of the cooling element 106 is determined from a look-up table stored in a memory 204 of the device 100 for controlling the speed based on the comparisons. The look-up table maps different speeds of the cooling element 106 or the corresponding noise generated to different temperature ranges of the hotspot temperature and to different temperature ranges of a difference between the ambient temperature and the hotspot temperature.

Although the steps of the methods 400 and 500 have been described as a particular sequence of steps, the steps may be performed in any suitable sequence or some of the steps may be performed simultaneously.

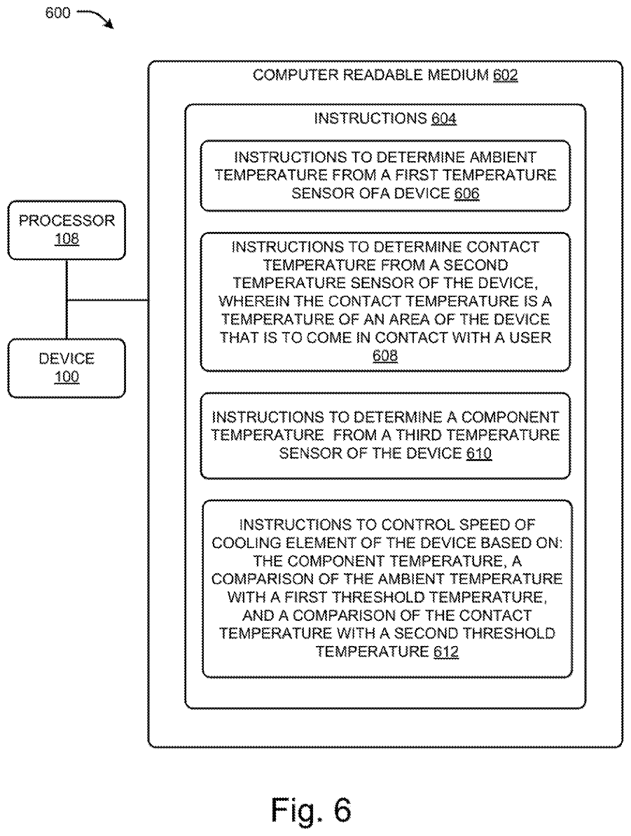

FIG. 6 illustrates a computing environment 600 implementing a computer readable medium for controlling speed of a cooling element, such as the cooling element 106 of the device 100, according to an example implementation of the present subject matter. In an example, the computing environment 600 includes a device 100 and the processor 108 communicatively coupled to a computer readable medium 602. The computer readable medium 602 may be, for example, an internal memory device or an external memory device. In some examples, the computer readable medium 602 may be a part of the memory 204.

In an example implementation, the computer readable medium 602 includes a set of computer readable instructions 604, which can be accessed by the processor 108 and subsequently executed to perform acts for controlling the speed of the cooling element 106 in the device 100.

For controlling the speed of the cooling element 106, an ambient temperature may be determined from a first temperature sensor of the device 100, according to instructions 606. A contact temperature of the device 100 may be determined from a second temperature sensor of the device 100, according to instructions 608. As explained before, the contact temperature is a temperature of an area of the device 100 that is to come in contact with a user. A component temperature of the device 100 may be determined from a third temperature sensor of the device 100, according to instructions 610. In one example, the component temperature may be a hotspot temperature caused by a heat-generating component of the device 100.

Instructions 612 cause the processor 108 to control the speed of the cooling element 106 based on the component temperature, a comparison of the ambient temperature with a first threshold temperature, and a comparison of the contact temperature with a second threshold temperature.

In an example, when the ambient temperature is greater than the first threshold temperature, the computer-readable instructions when executed by the processor 108 cause the processor 108 to increase the speed of the cooling element 106 as a difference between the component temperature and the ambient temperature increases. For example, the speed of the cooling element 106 may be controlled based on the range of temperature in which the difference between the component temperature and the ambient temperature falls, as described earlier.

In another example, when the ambient temperature less than the first threshold temperature, the computer-readable instructions when executed by the processor 108 cause the processor 108 to increase the speed of the cooling element 106 as the component temperature increases. For example, the speed of the cooling element 106 may be controlled based on the range of temperature in which the component temperature falls, as described earlier.

In another example, when the contact temperature is greater than the second threshold temperature, the computer-readable instructions when executed by the processor 108 cause the processor 108 to increase the speed of the cooling element 106 to a higher speed than a current speed.

The preceding description has been presented to illustrate and describe examples of the principles described. This description is not intended to be exhaustive. Many modifications and variations are possible in light of the above teaching.

1. A device comprising:
a first temperature reader to measure an ambient temperature in vicinity of the device;
a second temperature reader to measure a component temperature of a component of the device;
a cooling element; and
a processor to control a speed of the cooling element based on a comparison of the ambient temperature with a first threshold temperature and based on one of: the component temperature and a difference between the ambient temperature and the component temperature.

2. The device of claim 1, further comprising a third temperature reader to measure a contact temperature, wherein the contact temperature is a temperature of an area of the device that is to come in contact with a user, and wherein the speed of the cooling element is controlled based on a comparison between the contact temperature and a second threshold temperature.

3. The device of claim 2, wherein the first, second, and third temperature readers are thermocouples disposed between a first thermally conductive substrate and a second thermally conductive substrate.

4. The device of claim 2, wherein:
the first temperature reader is disposed on a portion of a device chassis that is away from heat-generating components;
the second temperature reader is disposed on the device chassis in proximity to the component that is a heat-generating component of the device; and
the third temperature reader is disposed on the device chassis in the area of the device that is to come in contact with the user.

5. The device of claim 1, further comprising a memory to store a look-up table, wherein the look-up table is to map different speeds of the cooling element to different temperature ranges of the component temperature and to different temperature ranges of a difference between the ambient temperature and the component temperature, and wherein the processor is to control the speed of the cooling element based on the look-up table.

6. The device of claim 1, wherein
when the ambient temperature is less than the first threshold temperature, the speed of the cooling element is controlled based on the component temperature; and
when the ambient temperature is greater the first threshold temperature, the speed of the cooling element is controlled based on a temperature difference between the component temperature and the ambient temperature.

7. A method comprising:
determining an ambient temperature from a first temperature sensor of a device;
determining a contact temperature of the device from a second temperature sensor of the device, wherein the contact temperature is a temperature of an area of the device that is to come in contact with a user; and
controlling a speed of a cooling element of the device based on a comparison of the ambient temperature with a first threshold temperature and a comparison of the contact temperature with a second threshold temperature.

8. The method of claim 7, further comprising determining a hotspot temperature in the device from a third temperature sensor, wherein when the ambient temperature is less than the first threshold temperature, the speed of the cooling element is controlled based on a range of temperature that the hotspot temperature falls within.

9. The method of claim 7, further comprising determining a hotspot temperature in the device from a third temperature sensor, wherein when the ambient temperature is greater than the first threshold temperature, the speed of the cooling element is controlled based on a range of temperature that a difference between the hotspot temperature and the ambient temperature falls within.

10. The method of claim 7, further comprising determining the speed of the cooling element from a look-up table for controlling the speed based on the comparisons, wherein the look-up table maps different speeds of the cooling element to different temperature ranges of a hotspot temperature and to different temperature ranges of a difference between the ambient temperature and the hotspot temperature.

11. The method of claim 7, comprising increasing the speed of the cooling element to a speed higher than a current speed when the contact temperature is greater than the second threshold temperature.

12. A computer readable medium comprising computer-readable instructions, the computer-readable instructions when executed by a processor cause the processor to:
determine an ambient temperature from a first temperature sensor of a device;
determine a contact temperature of the device from a second temperature sensor of the device, wherein the contact temperature is a temperature of an area of the device that is to come in contact with a user;
determine a component temperature of the device from a third temperature sensor of the device; and
control a speed of a cooling element of the device based on: the component temperature, a comparison of the ambient temperature with a first threshold temperature, and a comparison of the contact temperature with a second threshold temperature.

13. The computer readable medium of claim 12, further comprising computer-readable instructions that when executed by the processor cause the processor to increase the speed of the cooling element as a difference between the component temperature and the ambient temperature increases, when the ambient temperature is greater than the first threshold temperature.

14. The computer readable medium of claim 12, further comprising computer-readable instructions that when executed by the processor cause the processor to increase the speed of the cooling element as the component temperature increases, when the ambient temperature is less than the first threshold temperature.

15. The computer readable medium of claim 12, further comprising computer-readable instructions that when executed by the processor cause the processor to increase the speed of the cooling element to a higher speed than a current speed when the contact temperature is greater than the second threshold temperature.
